(19) United States
(12) Patent Application Publication
(10) Pub. No.: US 2011/0268891 A1
(43) Pub. Date: Nov. 3, 2011

(54) GAS DELIVERY DEVICE

(75) Inventors: John MacNeil, St. Nicholas (GB); Robert Jeffrey Bailey, Scotts Valley, CA (US)

(73) Assignee: SPP PROCESS TECHNOLOGY SYSTEMS UK LIMITED, Gwent (GB)

(21) Appl. No.: 13/054,033

(22) PCT Filed: Jul. 13, 2009
(86) PCT No.: PCT/GB2009/001731

§ 371 Date: Mar. 9, 2011

Related U.S. Application Data
(60) Provisional application No. 61/081,463, filed on Jul. 17, 2008.

(30) Foreign Application Priority Data
Sep. 5, 2008 (GB) 0816186.1

(51) Int. Cl. C23C 16/455; C23C 16/44; C23C 16/48; C23C 16/458; C23C 16/50

(52) U.S. Cl. 427/569; 118/715; 118/730; 427/248.1; 427/595; 427/587; 118/723 R; 118/722

(57) ABSTRACT

A gas delivery device is for use in low pressure Atomic Layer Deposition at a substrate location. The device includes a first generally elongate injector for supplying process gas to a process zone, a first exhaust zone circumjacent the process zone, and a further injector circumjacent the first exhaust gas for supplying purge or inert gas at an outlet surrounding the process zone having a wall for facing the location circumjacent the outlet to define at least a partial gas seal.

This invention relates to gas delivery devices and process chambers for use in low pressure Atomic Layer Deposition and methods of performing low pressure Atomic Layer Deposition.

The process of Atomic Layer Deposition (ALD) is well known. Essentially it comprises depositing a chemical layer such that a first monolayer is chemically absorbed into the surface of the substrate and then blowing away the excess material using a purge gas, which can also be used to purge the process chamber so that a further monolayer can be laid down, which may be of the same or a different chemistry.

ALD can be performed both at atmosphere and low pressure. At atmospheric pressure, large quantities of gas have to be supplied, because of the ambient pressure to be overcome and the resultant gas flow rates mean that the substrate tends to see a line or cone of a process gas under which it progressively sweeps. In contrast, at low pressures, smaller quantities of gas at slower flow rates can be supplied allowing the gas to diffuse whereby up to the whole of the surface of a substrate can be treated simultaneously. Accordingly for economic and uniformity reasons, there are significant advantages in low pressure ALD, but the very different flow characteristics mean that methods and techniques developed for atmospheric ALD cannot be automatically incorporated into low pressure ALD configurations.

To date, most ALD, whether atmospheric or low pressure operate on single wafers. As with most deposition processes, there is a considerable economic advantage if one can achieve batch processing, provided that uniformity is maintained.

Various approaches have been suggested whereby one might achieve batch ALD. U.S. Pat. No. 6,821,563 is not an untypical example and another approach can be seen in U.S. Pat. No. 7,104,476. Each of these assumes that a wafer will track along a circular path under a variety of process sectors. In this arrangement the processing of the wafers is dictated entirely by the slowest process to be performed and there is little flexibility in use. Further, the injector sectors are divergent and in practice only a small part of the sector is used or there are significant uniformity issues. A not dissimilar arrangement is suggested in 2005/0084610, whilst US 2007/007356 suggests a linear approach.

Another attempt is set out in U.S. Pat. No. 6,902,620. This uses a plurality of shower heads in a single chamber and seeks to separate active process areas by having the intermediate shower heads supplied with an inert gas, where reactions between the process gases may take place. It is far from clear that the arrangement suggested is practical in nature, because it would appear extremely difficult to perform a full diametric argon ‘curtain’ diametrically across the chamber using such a technique.

As far back as 1989, see for example U.S. Pat. No. 4,834,020, linear injectors for CVD have been known in which a gas could be delivered to a process area and then exhausted either side of that process area. Inert or purge gas can be supplied on either side of the process area. The most sophisticated arrangement of this is probably shown in U.S. Pat. No. 6,200,389. It will be noted that “sealing” is only described in the linear direction of travel of the substrates being treated.

From one aspect the invention consists in a gas delivery device for use in low pressure Atomic Layer Deposition at a substrate location including a first generally elongate injector for supplying process gas to a process zone; a first exhaust zone circumjacent the process zone; and a further injector circumjacent the first exhaust gas for supplying purge or inert gas at an outlet surrounding the process zone having a wall for facing the location circumjacent the outlet to define at least a partial gas seal.

For the purposes of this specification a partial gas seal is one in which the leakage is below 10,000 ppm.

The injector preferably has one or more lines of ports and the process area may be between 15 mm and 25 mm in height so as to allow diffusion of the process gas whereby a substrate may effectively see a uniform cloud or mist of process gas.

There may be a plasma area defined by inner and outer purge gas injectors and this may lie within the partial gas seal.

The device may further include a further gas exhaust area circumjacent at the further injector.

From another aspect the invention may include a gas delivery device locatable in the process chamber and having a gas seal around its complete perimeter.

The device may further include a further gas exhaust area circumjacent the further injector.

From a further aspect the invention consists in a low pressure Atomic Layer Deposition apparatus for forming layers on a substrate including a process chamber having at least one gas injector and at least one gas delivery device as defined above and a rotatable support for moving substrates around the chamber and through the gas delivery device process area.

The apparatus may further include a control for rendering the gas delivery device operative or inoperative whereby a substrate can be processed in the process chamber alone or successively by the gas delivery device and the process chamber or vice versa in accordance with the process to be performed on the substrate.

The partial gas seal may at least in part be constituted by a passage of between about 1.5 mm and about 3 mm wide. The passage may be defined, in use, by the distance between the surface of the substrate (e.g. a semi-conductor wafer) and the face of the wall facing the location. Conveniently that wall may extend symmetrically on either side of the outlet or it may extend simply on one side of the outlet, preferably that furthest from the process area.

The partial gas seal may be at least in part constituted by a passage, such as indicated above, of between about 30 mm and about 100 mm in length and particularly conveniently the passage about 60 mm and about 100 mm in length and between about 1.5 and about 3 mm wide. These dimensions may vary somewhat depending on the size of the molecules of the gas or gasses being used as process gasses or purge gasses. They will also be scalable depending on the gas pressures and the pressure drop between the zone and the chamber.

Preferably the pressure in the process area is not more than about +/−0.25 Torr (±30 Pa) than the 1 Torr pressure in the chamber. (1 Torr˜133.3 Pa)

The velocity of the gas at the further injector may be at least about 50 m/s. The velocity or flow rate should not exceed the exhaust capabilities of the gas delivery system.

From a still further aspect the invention consists in a method of performing low pressure Atomic Layer Deposition in the process chamber including a gas delivery device having a full perimeter seal to define a separate process area from the process chamber and a rotatable support for moving substrates around the process chamber and through the process area wherein, in the method, the substrates are, during at least part of the method, processed both in the chamber and the process area.

For example, the gas delivery device may be switched off during one or more rotations of the support. This enables the substrates, e.g. semi-conductor wafers, to be exposed to a process gas in the process chamber for a desired period and then to have subsequent processing in the process area. This is a particularly useful way of processing wafers in a batch, when the process times are significantly unequal. Thus a process gas may be supplied to the process chamber or a purge gas, for removing excess deposition, may be supplied to the chamber, in which case the gas delivery device may perform the other process or processes.

As there is a full seal around the gas delivery device, cross-contamination between the processes should not occur.

Although the invention has been defined above, it is to be understood it covers any inventive combination of the features set out above or in the following description.

The invention may be performed in various ways and specific embodiments will now be described, by way of example, with reference to the accompanying drawings, in which:

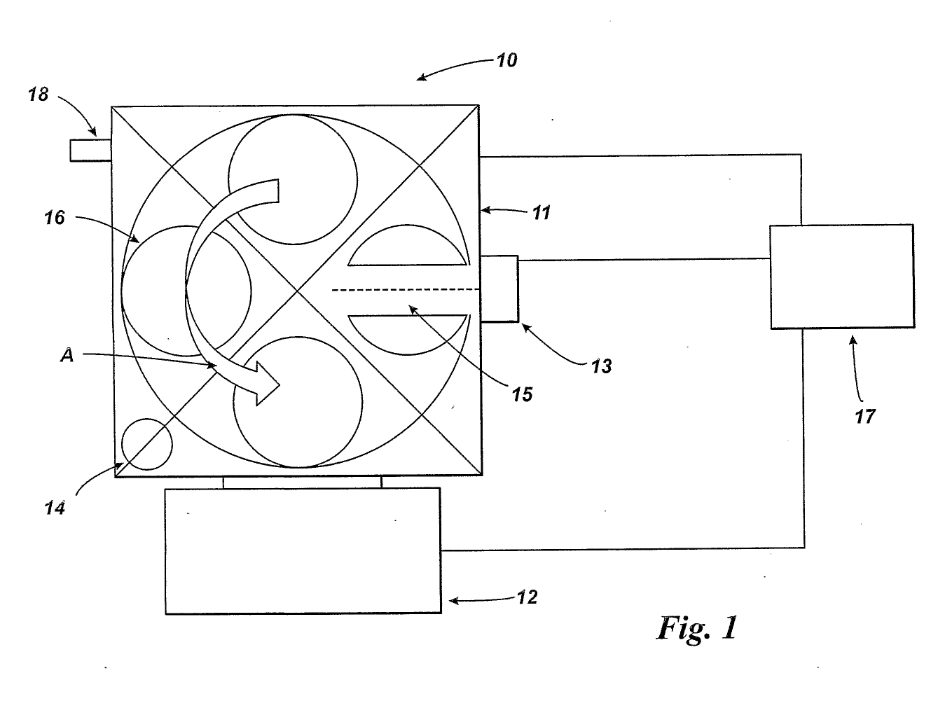

FIG. 1 is a plan view of a particularly simple embodiment of the invention;

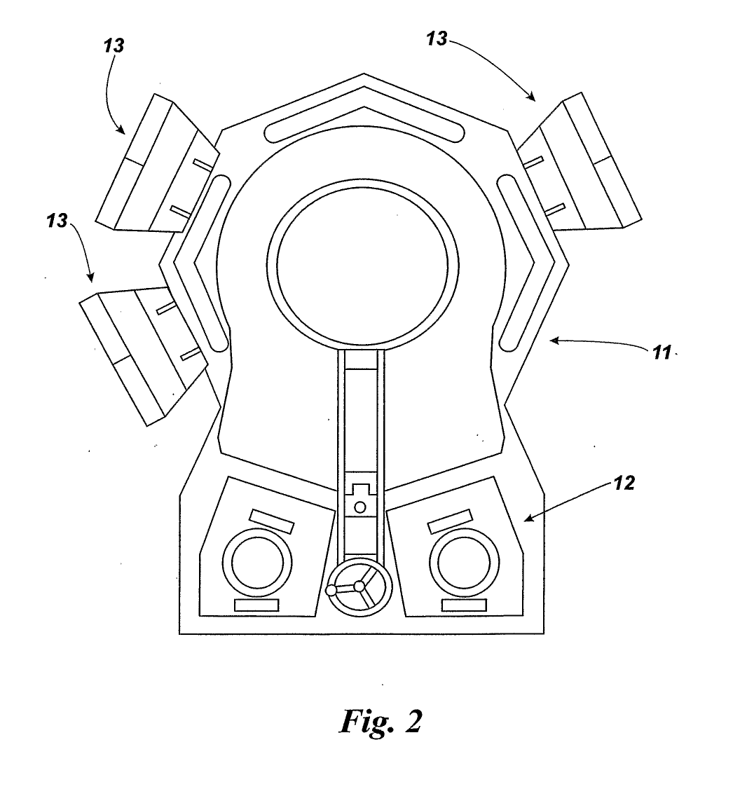

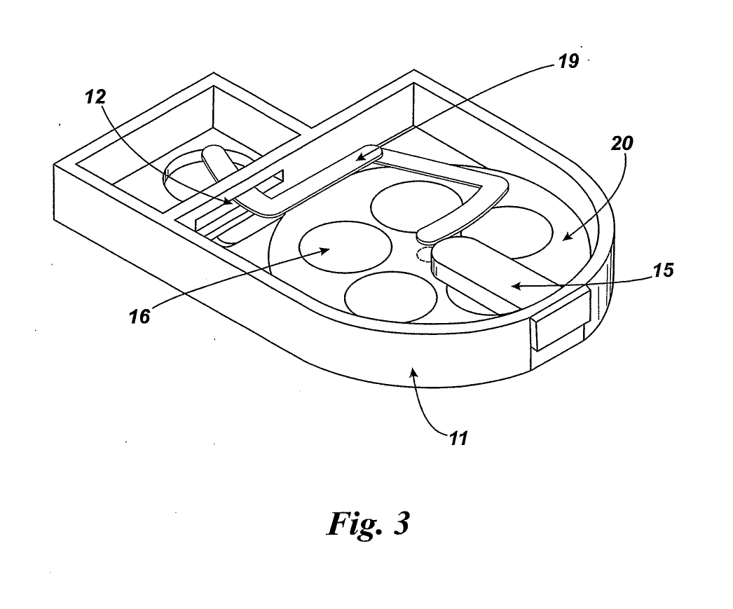

FIG. 2 is a corresponding plan view of a more complex batch processor;

FIG. 3 is a more detailed schematic view of a further embodiment of a batch processor;

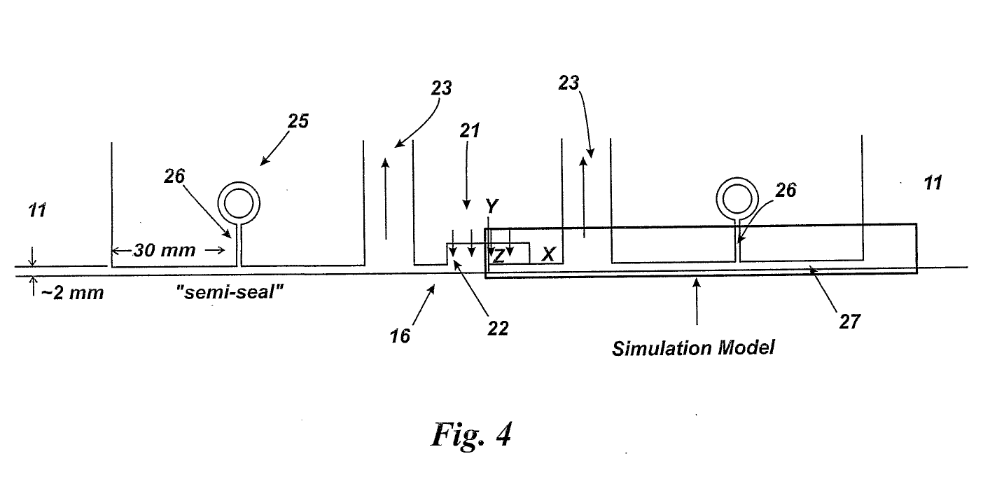

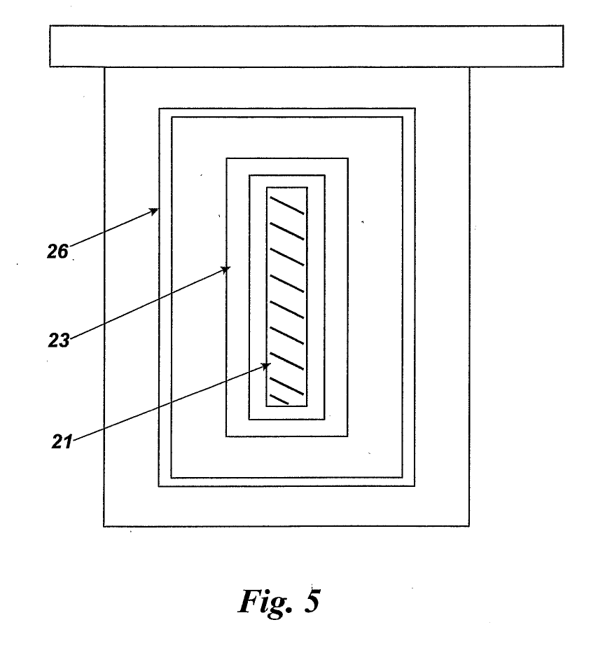

FIG. 4 is a schematic sectional view through a gas delivery device taken along the line IV-IV in FIG. 5;

FIG. 5 is a plan view;

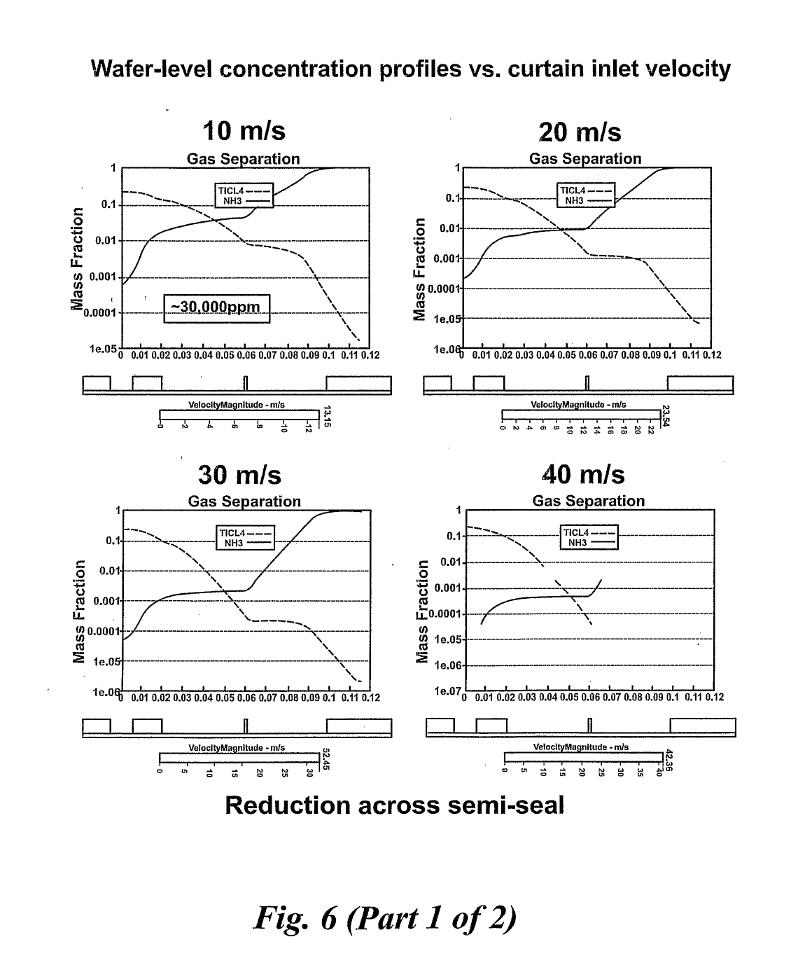

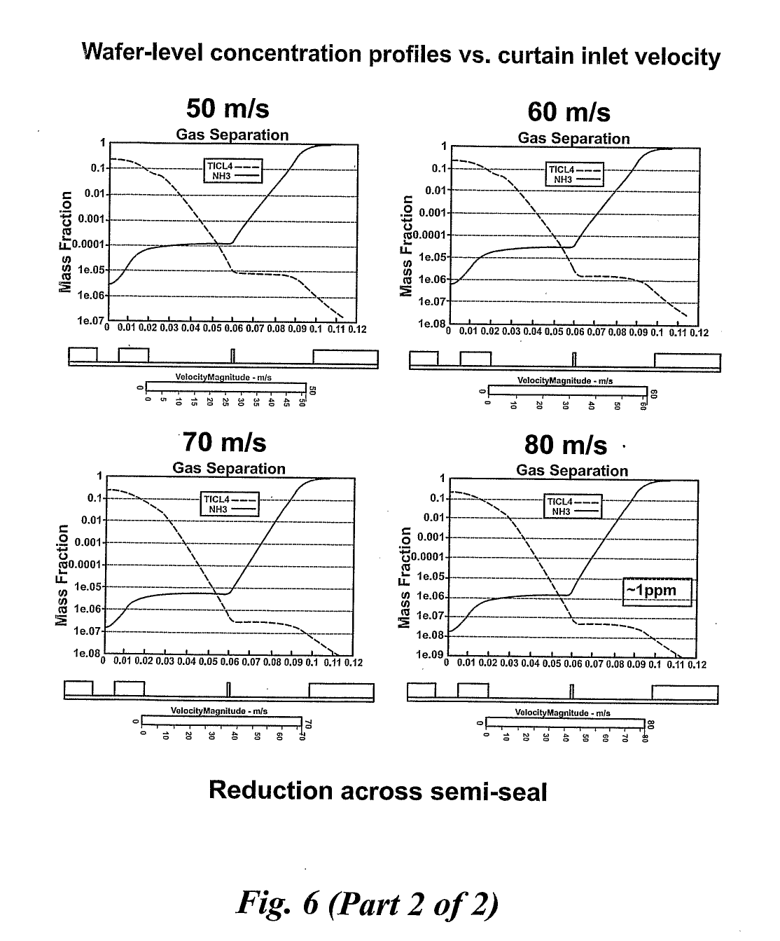

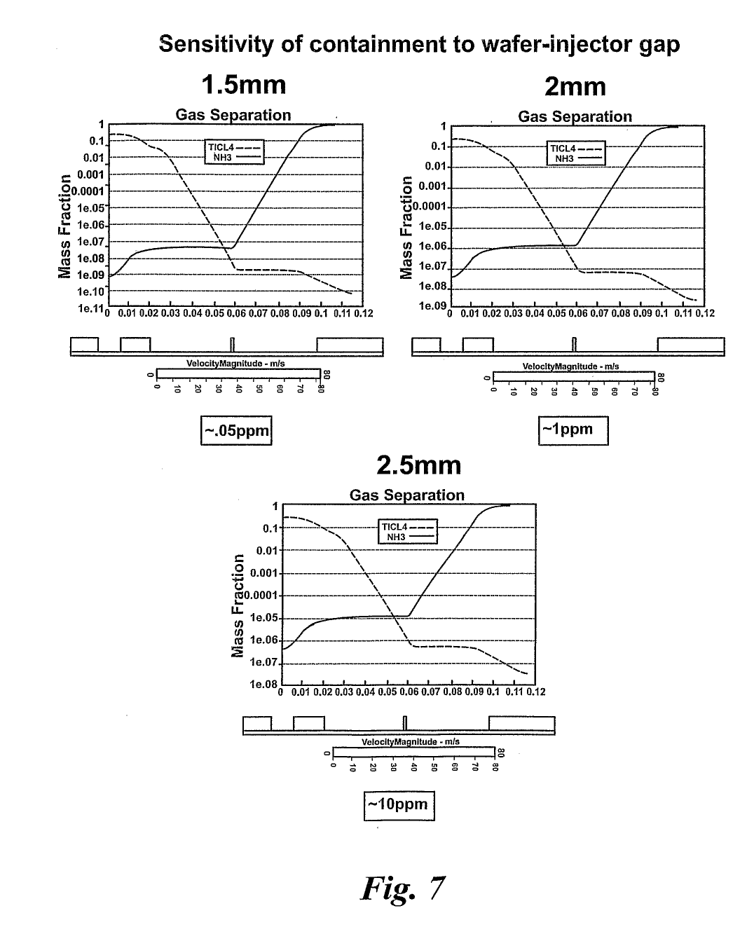

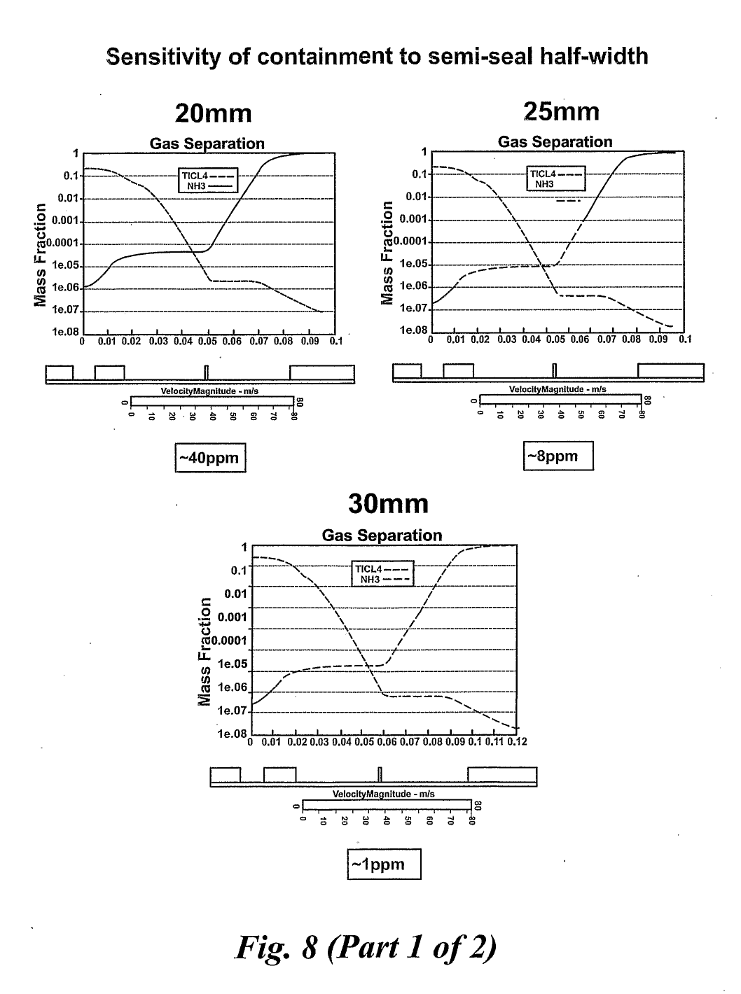

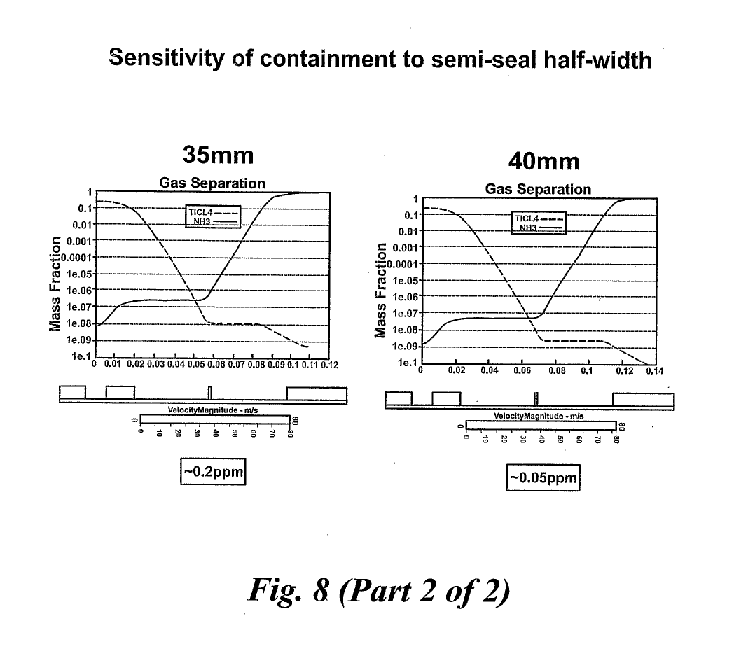

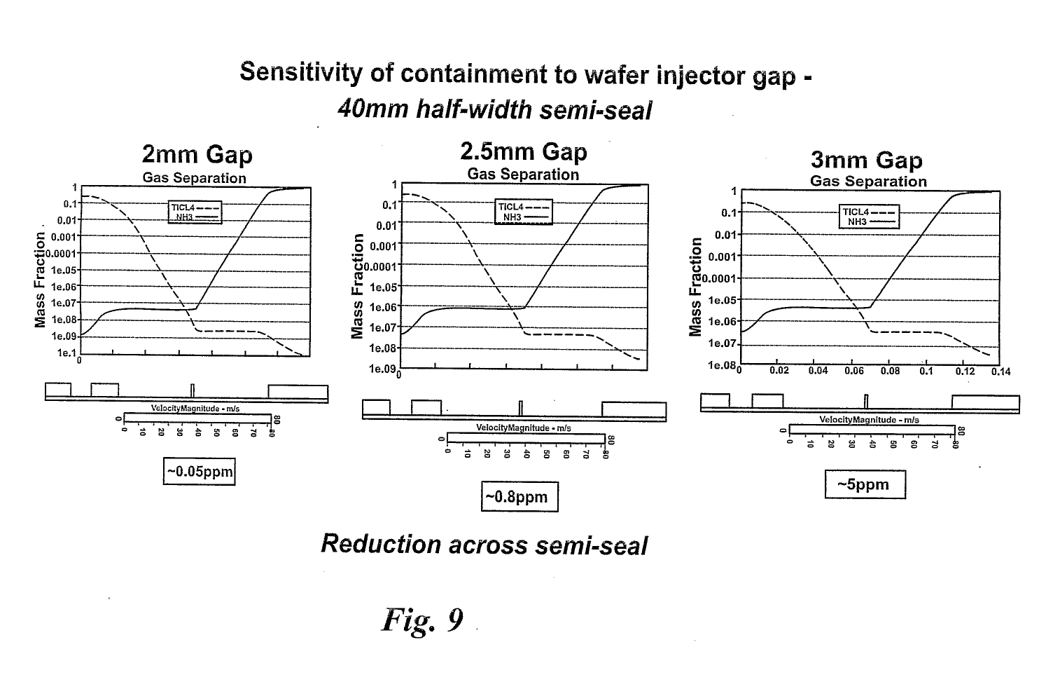

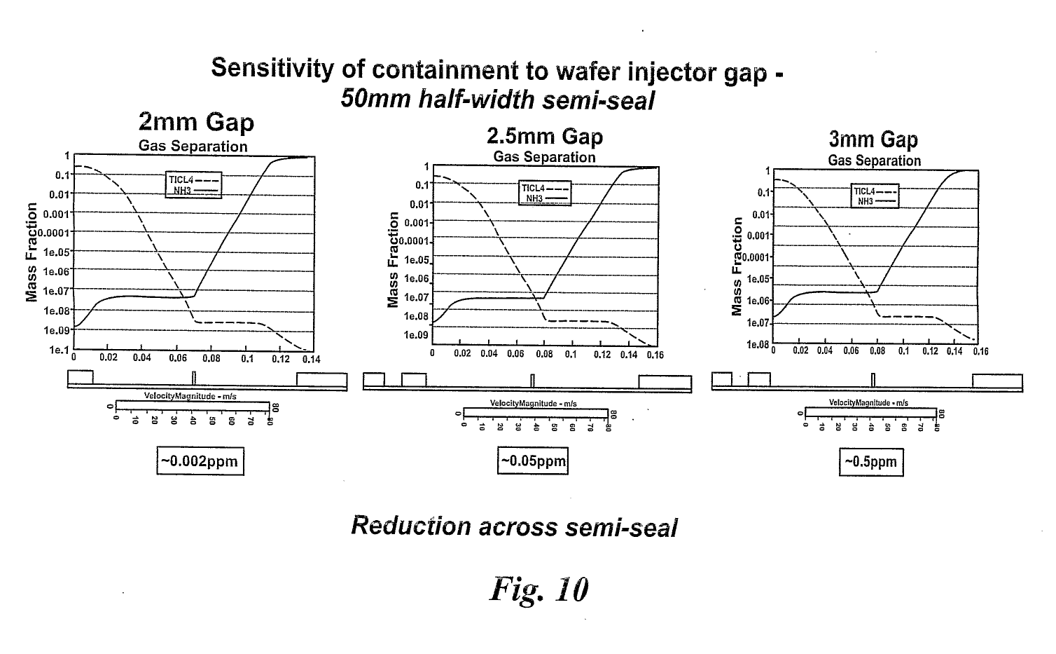

FIGS. 6 to 10 are a series of graphs illustrating the results of simulation modelling on the section of the gas delivery device indicated in FIG. 4 showing the results of varying various parameters on the effectiveness of the seal. In each case the line extending from the left hand axis and descending indicates the density of TiCl₄ at the location taken from the centre of a process area and the other line descending from right to left is the density of NH₃;

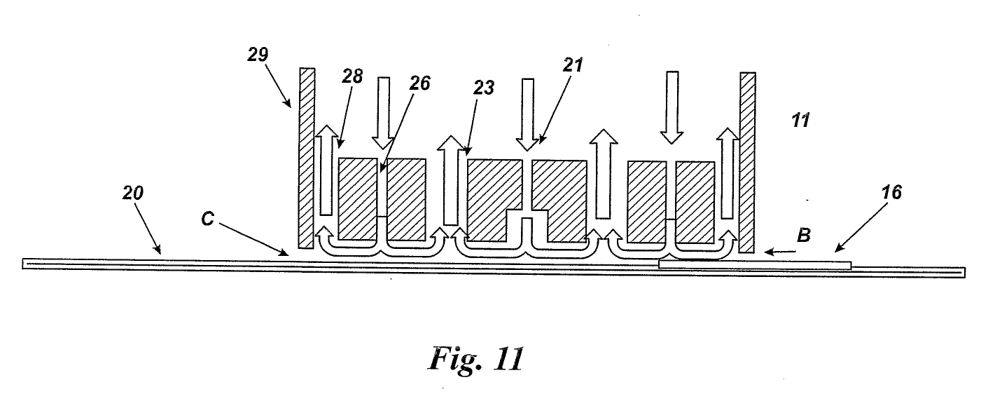

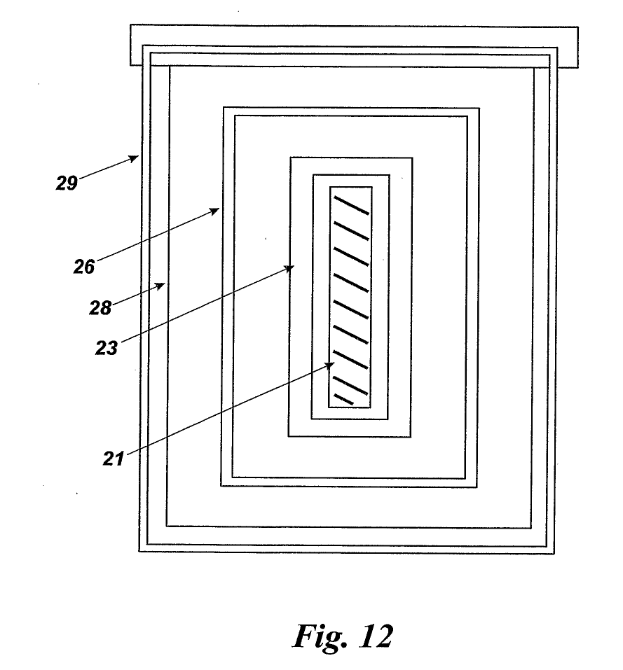

FIGS. 11 and 12 correspond to FIGS. 3 and 4 for an alternative embodiment of the gas delivery device; and

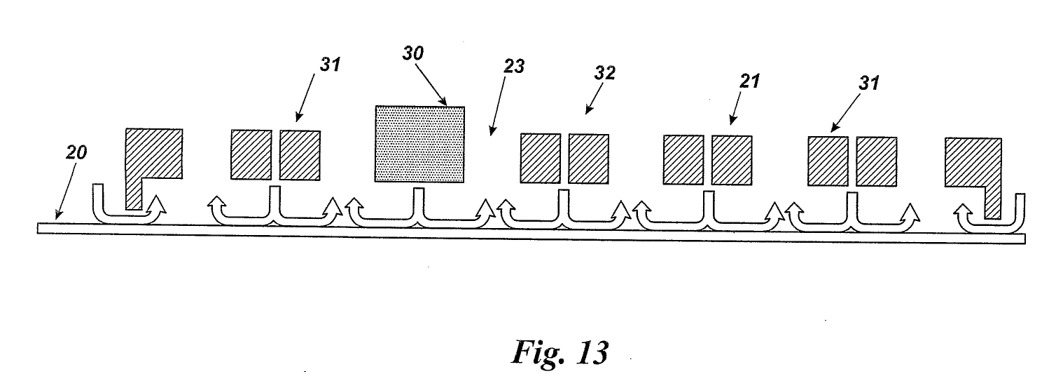

FIG. 13 is a schematic view of a gas delivery device illustrating the incorporation of a plasma treatment stage.

FIG. 1 illustrates apparatus 10 suitable for use in low pressure ALD. The apparatus 10 has a process chamber 11 which can be supplied through a standard load lock arrangement generally indicated at 12 whereby wafers can be automatically fed into and removed from the chamber 11. An ejector 13 extends into the chamber 11. Chamber 11 is evacuated through pump port 14. Typical pressures would be in the region of 0.5-10 Torr.

As will be described in more detail below, the injector device 15 of the injector 13 has a central element for supplying a process gas and this element is effectively 360° sealed from the main process chamber 11, in the sense that gas can neither come in from the process chamber to the central process area of the gas delivery device 15 nor can process gas escape from the device 15 into the process chamber 11. As is indicated schematically by the arrow A, the process chamber contains a rotatable support of the type that is well-known in the art on which substrates 16, such as semi-conductor wafers, can sit and be rotated around the chamber to pass under the gas delivery device 15. A control 17 is provided for rendering the gas delivery device 15 operative or inoperative and the control may also control other aspects of the apparatus 10, such as the rate of rotation of the support and the operation of the load lock 12.

The process chamber 11 may be provided with one or more process gas inlets, one of which is schematically illustrated at 18.

In use, wafers may be introduced onto the support in a batch and rotated around the chamber 11. Depending upon the chemistry which is intended, the chamber 11 may contain a purge gas, at least at some stages of the process, and the gas delivery device 15 may or may not be operative at different stages of the process.

By way of example, TiN can be deposited by first treating the surface of the substrate 16 with NH₃ and then subsequently being exposed to TiCl₄. The usual exposure to NH₃ is over a second, whilst an exposure of less than 0.1 seconds to TiCl₄ is required. This can very conveniently be achieved in the chamber 11 by switching the gas delivery system off initially; supplying NH₃ to the process chamber 11 for the desired period and then switching on the gas delivery device 15 to supply TiCl₄. It will often be possible to balance the timing within one rotation for example by altering the concentration of the TiCl₄. In this case the NH₃ could be left on permanently. The wafers may be rotated during all stages to make sure that one does not lie beneath the gas delivery system 15 during the first part of the process or the support can be static with a gap corresponding to the gas delivery device 15.

Such large exposure disparities are difficult to accommodate with the apparatus described in the prior art. However, it will equally be appreciated that the apparatus of the present invention can equally well accommodate processes where the deposition periods for gas is similar. The apparatus can also be used with the process chamber 11 may be filled with purge gas to remove excess material when the substrate 16 emerges from the gas delivery devices 15.

In FIG. 2, the same sort of arrangement is shown but the possibility of having more than one gas delivery device is illustrated.

FIG. 3 illustrates an embodiment apparatus 10 which has been specifically designed for the purpose, rather than FIGS. 1 and 2 which utilise a standard chamber and loadlock. In particular a rotatable platen 20 is illustrated carrying five wafers 16. Robot arm 19 transfers wafers 16 to and from platen 20 to loadlock 12.

The nature of the gas delivery device 15 is shown in more detail in FIGS. 4 and 5. Here it will be seen that there is a central injector 21 for enabling, for example the injection of TiCl₄. The injector 21 defines a process area or zone 22 and is surrounded by an exhaust duct 23. This in turn is surrounded by a thick wall 24 that contains a rectangular argon inlet 25.

In use, wafers pass from, say right to left, from the chamber 11 beneath a portion of the wall 25 underneath the argon curtain created by the inlet 26, past the exhaust 23 through the process area 22 and then continue outwardly until they reach the chamber 11 again.

It will be understood that the majority of the TiCl₄ is exhausted by the surrounding exhaust 23. Any which diffuses beyond the exhaust 23 then has to pass down a passage 27 where it is likely to be captured by the argon curtain created by inlet 26 and driven back towards the exhaust 23. By making the width of the passage as small as is viable without risking damage to the wafers or creating excessive drag, the likelihood of any molecules escaping down the passage is significantly reduced. The length of the passage is also a relevant factor. Another factor is the rate of flow of the argon through the outlet 26.

As far as the NH₃ is concerned the same criteria of passage dimension and air curtain reduced the likelihood of diffusion from the chamber through to the process area 22. Even if molecules get to the left hand end of the passage 27 they will likely be exhausted by the exhausts 23.

FIGS. 6 to 10 show how a chamber 11 operating at process pressure of 1 T and platen 20 temperature of 300 C where the parts per million either exiting from the process area 22 or ingressing from the chamber 11 vary with variations in the parameters mentioned above. It will be seen that the half-width of the wall 25 (also known as the semi-seal) can make a particularly significant difference as can the gap, which is the width of the passage 27. The greater the half width the greater the acceptable gap.

In certain circumstances it may only be necessary for the passage to extend between the argon inlet and the chamber 11. This would be particularly true if only low flow rates of the gas into the process area where required and essentially the passage was simply trying to prevent ingress of NH₃.

FIGS. 11 and 12 illustrate a further embodiment of a gas delivery device 15. Here a gas delivery element 21 lies within an exhaust chamber 23 defined by a surrounding rectangular inert gas supply 26 which in turn lies within a further exhaust chamber 28 defined by a perimeter wall 29.

As can be seen in FIG. 11, in use the gas delivery device 15 may be located just above a rotating support 20 so that wafers 16 can be passed beneath the bottom edge of the wall 29 to travel in the direction indicated by the arrow B, wherein they pass through the exhaust chamber 28, beneath the inert gas supply 26 through the exhaust chamber 23 into a process area 22 beneath the supply 21. The process area 22 can be large enough to accommodate the whole wafer 16 at a single time or it may be narrower than the diameter of the wafer although it will extend longitudinally for at least the diameter of the wafer.

The wafer then passes out of the device 15 still continuing in the same direction.

As can be seen in FIG. 11 the chambers 23 and 28 are evacuated, for example by being connected to pump 19. Argon is supplied to the inert gas inlet 26 where it forms an effective inert gas screen around the exhaust chamber 23 and hence the process area and can also act as a purge gas. Any gas which leaks under the wall 29 (see broken arrow C) is evacuated through chamber 28 and/or blocked by the argon curtain. Similarly, a process gas such as TiCl₄ supplied to 21 passes through the process area 22 and is exhausted through chamber 23. It is prevented from exiting laterally by the argon curtain.

The designs of FIGS. 5 and FIGS. 11 and 12 therefore provides a 360° seal around the process gas 21 and thus isolates that process area 22 from the rest of the process chamber 11. This feature particularly enhances the flexible usage of the apparatus 10 as described above. The ability to isolate in this manner can also be further utilised by arranging for a more complex gas delivery head 15, such as is illustrated in FIG. 13. Here a plasma process area, generally indicated at 30 is surrounded by a first purge supply 31 and divided from the process area 22 by a second purge supply 32. In this way, the surface of the substrate can either be prior plasma treated or post plasma treated as desired. This active area 30 could alternatively provide UV or hot wire excitations. Similarly such sources can be provided in the chamber 11 to excite the process gas.

It will be understood that the principals of the gas delivery device 15 illustrated and described with reference to FIGS. 5, 11 and 12 and 13 can be incorporated in heads of different geometry and with more complex succession of process areas.

1. A gas delivery device for use in low pressure Atomic Layer Deposition at a substrate location including a first generally elongate injector for supplying process gas to a process zone; a first exhaust zone circumjacent the process zone; and a further injector circumjacent the first exhaust gas for supplying purge or inert gas at an outlet surrounding the process zone having a wall for facing the location circumjacent the outlet to define at least a partial gas seal.

2. A device as claimed in claim 1, wherein there is an active area (plasma/UV or hot wire excitation) defined by inner and outer purge gas injectors and within the further exhaust area.

3. A device as claimed in claim 1, wherein the process area is between 10 mm and 40 mm in height.

4. A gas delivery device as claimed in claim 1 further including a further gas exhaust area circumjacent the further injector.

5. A gas delivery device locatable in a process chamber and having a gas seal around its compete perimeter to define a gas process area.

6. A low pressure Atomic Layer Deposition apparatus for forming layers on a substrate including a process chamber having at least one gas injector and at least one gas delivery device as claimed in claim 5 and rotatable support for moving substrates around the chamber and through the gas delivery device process area.

7. Apparatus as claimed in claim 6, further including a control for rendering the gas delivery device operative or inoperative whereby a substrate can be processed in the process chamber alone or successively by the gas delivery device and the process chamber or vice versa in accordance with the process to be performed on the substrate.

8. Apparatus as claimed in claim 5 wherein the partial gas seal is at least in part constituted a passage of between about 1.5 and about 3 mm wide results in a containment of <10,000 ppm between reactive zones.

9. Apparatus as claimed in claim 5 wherein the partial gas seal is at least in part constituted by a passage of between about 30 mm and about 100 mm in length.

10. Apparatus as claimed in claim 9 wherein the passage is between about 60 mm and about 100 mm in length and between about 15 and 3 mm wide.

11. Apparatus as claimed in claim 5 wherein the pressure in the process area is not more than about ±50%—of the pressure in the chamber.

12. Apparatus as claimed in claim 5 wherein the pressure in the process area is not more than about ±50%—of the pressure in the chamber.

13. Apparatus as claimed in claim 5 wherein the velocity of gas at the further injector is at least about 50 m/s.

14. A method of performing Atomic Layer Deposition in a process chamber including a gas delivery device having a full perimeter seal to define a separate process area from the process chamber and a rotatable support for moving substrates around the process chamber and through the process area wherein the substrates are, during at least part of the method, processed both in the chamber and in the process area.

15. A method as claimed in claim 14, wherein the gas delivery device is switched off during one or more rotations of the support.

16. A method as claimed in claim 14, wherein a process gas is supplied to the process chamber.

17. A method as claimed in claim 14, wherein a process gas excited by plasma/UV or hot wire excitation is supplied to the process chamber.

18. A method as claimed in claim 14 wherein the chamber includes a plasma, UV or hot wire excitation source.

19. A method as claimed in claim 14, wherein a purge gas is supplied to the process chamber.
